(19) United States
(12) Patent Application Publication
(10) Pub. No.: US 2023/0203734 A1
(43) Pub. Date: Jun. 29, 2023

(54) Console HMI Interface Mechanism

(71) Applicant: Whirlpool Corporation, Benton Harbor, MI (US)

(72) Inventor: Arun Rajendran, St. Joseph, MI (US)

(21) Appl. No.: 17/563,528

(22) Filed: Dec. 28, 2021

(51) Int. Cl. D06F 34/30; H05K 5/00; H05K 5/02; D06F 34/34

(52) U.S. Cl. CPC D06F 34/30; H05K 5/0017; H05K 5/0226; D06F 34/34

(57) ABSTRACT

A household appliance has a cabinet (12) with working operable elements of the appliance (10). A control console (14) for the appliance (10) is associated with the cabinet (12). A human mechanical interface (20), supplying information to an user, is associated with the control console (14). The interface (20) moves with respect to the control console (14) to a desired viewing zone for the user. The interface (20) has a bezel (24) to hold the interface (20). The bezel (24) is rotatable with respect to the console (14). A rotary damper (28) is coupled with bezel (24) rotating the bezel (24). Activation of the rotary damper (28) enables the bezel (24) and interface (20) to rotate to one or more viewing zones.

### FIELD

The present disclosure relates to household appliances and, more particularly, to washer, dryer and combination washer/dryer machines with a movable human mechanical interface.

### BACKGROUND

In household appliances, such as washers, dryers and combination washer/dryers, they include a cabinet that receives the operable elements as well as a console. The console includes various types of controls for operation of the particular appliance. Generally, the consoles include an interface that provides the user with information and functioning of the appliance. Ordinarily, these interfaces are fixed to the console. The interface may be fixed at an angle with respect to the front surface of the console at the angle of the front face. Here, the front face is angled perpendicular to the ground or slightly angled with respect to the ground. This fixing or positioning of the interface is utilizable for viewing by a specific group of users. Thus, it does not cover all viewing of percentages of users.

Generally, a tall user is required to bend or kneel down in order to see the particular interface. Handicap people in wheelchairs may not be able to view the particular interface. Thus, a substantial percentage of users are unable to readily view the interface associated with the appliance console. Thus, it is desirable to provide a household appliance where the interfaces can be viewed by all users.

Accordingly, the present disclosure provides a mechanical human interface that is viewable by substantially all perspective users. The present disclosure provides an interface that is movable between positions to enable users of all heights to readily view and ascertain the information on the interface.

### SUMMARY

This section provides a general summary of the disclosure, and is not a comprehensive disclosure of its full scope or all of its features.

Accordingly to a first aspect of the disclosure, a household appliance comprises a cabinet with operable elements of the appliance within the cabinet. A control console is associated with and generally positioned on a front panel or on a top of the appliance. A human mechanical interface for supplying information to the user is associated with the control console. The interface moves with respect to the control console to provide a desired viewing zone for a user. The interface further comprises a bezel for holding the interface. The bezel is rotatable with respect to the console. A rotary damper is coupled with bezel to rotate the bezel. Activation of the rotary damper enables the bezel to rotate to one or more viewing zones. The bezel includes a pivot hinge defining an axis. The hinge is coupled with the rotary damper to enable rotation. The bezel is pushed to rotate away from or into the console to a position providing one of the desired viewing zones. An additional push on the bezel retracts the bezel to its original position with respect to the console. A ribbon cable is coupled between the interface and the controls of the appliance to enable positioning of the interface during its rotation into the viewing zones. The interface is angled with respect to a surface of the console at an angle of from about 0° to 45°. Also, the interface is positioned at an angle of about 0° to 30° with respect to an axis or plane of the viewer, which is substantially horizontal. The viewing zones compensate for various heights of the users.

Accordingly to a second embodiment of the disclosure, a human mechanical interface for a household appliance comprises an interface supplying information to a user. The interface may be coupled with a control console. The interface moves with respect to the control console to provide a desired viewing zone for the user. The interface further comprises a bezel for holding the interface. The bezel is rotatable with respect to the console. A rotary damper is coupled with bezel to rotate the bezel. Activation of the rotary damper enables the bezel to rotate to one or more viewing zones. The bezel includes a pivot hinge defining an axis. The hinge is coupled with the rotary damper to enable the rotation. The bezel is pushed to rotate away from or into the console to a position providing one of the desired viewing zones. An additional push on the bezel retracts the bezel to its original position with respect to the console. A ribbon cable is coupled between the interface and the controls of the appliance to enable positioning of the interface during its rotation into the viewing zones. The interface is angled with respect to a surface of the console at an angle of from about 0° to 45°. Also, the interface is positioned at an angle of about 0° to 30° with respect to an axis or plane of the viewer, which is substantially horizontal. The viewing zones compensate for various heights of the users.

According to a third aspect of the disclosure, a console for a household appliance comprises a housing defining a console. The housing includes a front face. An interface supplying information to a user may be coupled with a control console. The interface moves with respect to the control console to provide a desired viewing zone for the user. The interface further comprises a bezel for holding the interface. The bezel is rotatable with respect to the console. A rotary damper is coupled with bezel to rotate the bezel. Activation of the rotary damper enables the bezel to rotate to one or more viewing zones. The bezel includes a pivot hinge defining an axis. The hinge is coupled with the rotary damper to enable the rotation. The bezel is pushed to rotate away from or into the console to a position providing one of the desired viewing zones. An additional push on the bezel retracts the bezel to its original position with respect to the console. A ribbon cable is coupled between the interface and the controls of the appliance to enable positioning of the interface during its rotation into the viewing zones. The interface is angled with respect to a surface of the console at an angle of from about 0° to 45°. Also, the interface is positioned at an angle of about 0° to 30° with respect to an axis or plane of the viewer, which is substantially horizontal. The viewing zones compensate for various heights of the users.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a perspective view of an appliance in accordance with the present disclosure.

FIG. 2 is a perspective view of a console with the interface in a first and second position.

FIG. 3 is a cross-section view of FIG. 2.

FIG. 4 is an exploded perspective view of the interface.

FIG. 5A is a perspective view of a second embodiment of an appliance.

FIG. 5B is an elevation schematic view of FIG. 5A in a first position.

FIG. 5C is an elevation schematic view of FIG. 5A in a second position.

FIG. 5D is a schematic elevation view of FIG. 5A in a third position.

FIG. 6A is a perspective view of a second embodiment of an appliance.

FIG. 6B is an elevation schematic view of FIG. 6A in a first position.

FIG. 6C is an elevation schematic view of FIG. 6A in a second position.

FIG. 6D is a schematic elevation view of FIG. 6A in a third position.

FIG. 7A is a perspective view of a second embodiment of an appliance.

FIG. 7B is an elevation schematic view of FIG. 7A in a first position.

FIG. 7C is an elevation schematic view of FIG. 7A in a second position.

FIG. 7D is a is a schematic elevation view of FIG. 7A in a third position.

FIG. 8A is a schematic view of a linkage for an interface in a first position.

FIG. 8B is a schematic view of the linkage in a raised position like in FIG. 7B.

FIG. 8C is a schematic view with the interface tilted.

FIG. 8D is a schematic view of the linkage like that in FIG. 7D.

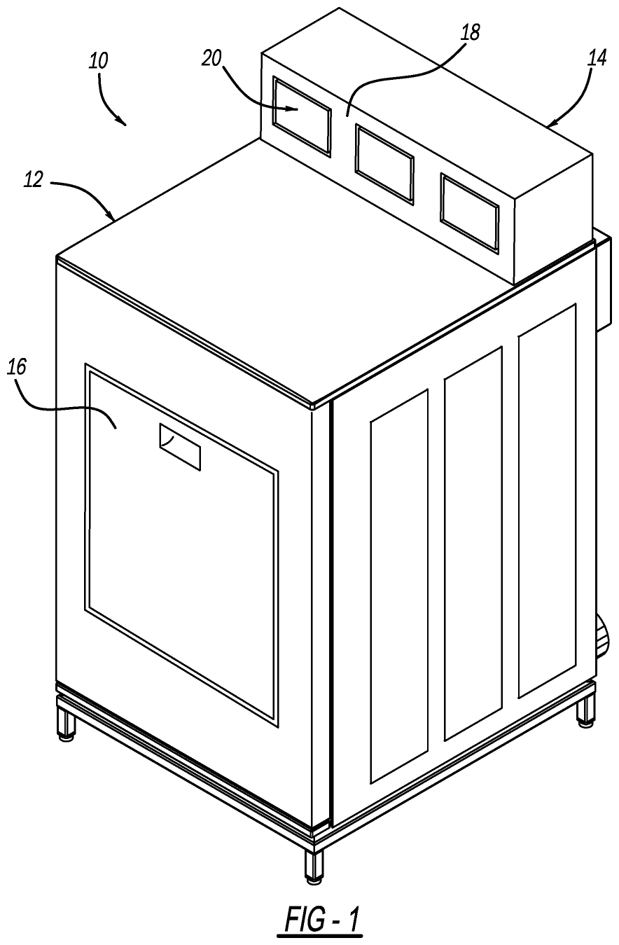

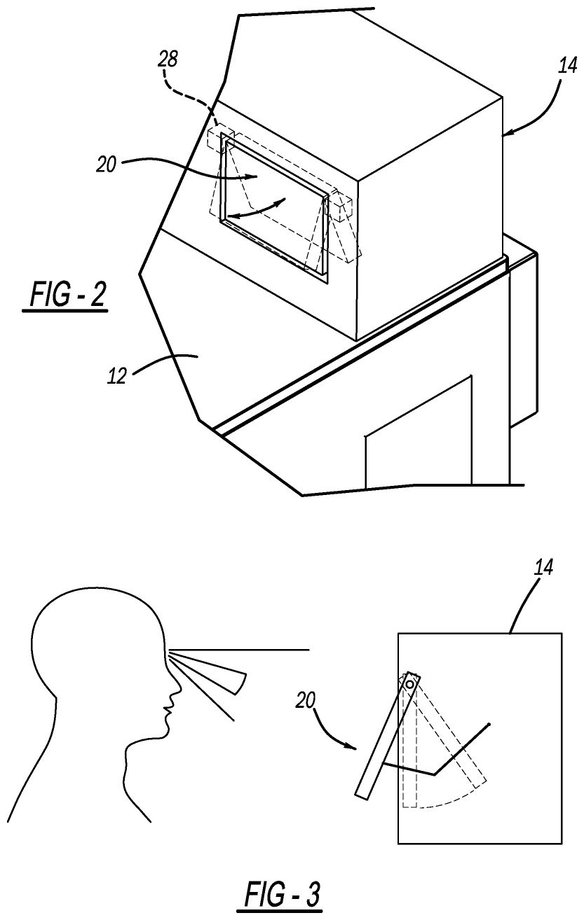

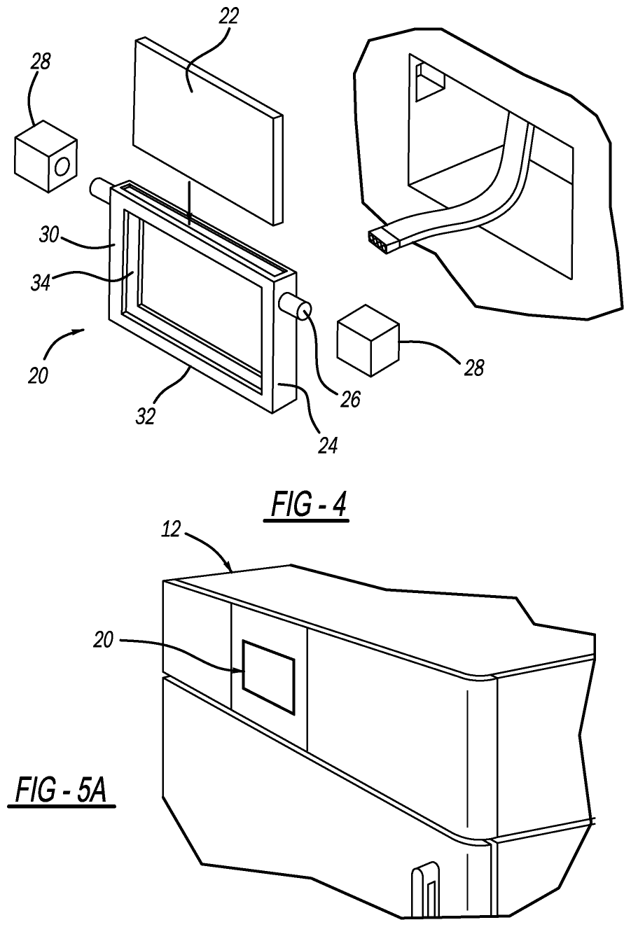

### DETAILED DESCRIPTION

Example embodiments will now be described more fully with reference to the accompanying drawings.

Turning to the figures, a household appliance is illustrated and designated with the reference numeral 10. The appliance includes a cabinet 12 with a console 14. The cabinet 12 includes a door 16 enabling access inside the cabinet to the working operable elements of the household appliance 10. The console 14 is illustrated as being on top of the cabinet 12. However, the console could be on a front face of the cabinet 12 as illustrated in phantom. The console 14 may include one or more interfaces 20. The interfaces 20 are human mechanical interfaces and provide the user with information on the appliance. The interface may provide information relating to functioning, using or operation of the appliance.

The interface 20 is movable from a first position, substantially flush with the front face 18 of the console 14, to at least one second position angled with respect to the console 14 as shown in FIG. 2. The angle with respect to the console from face 18 may vary between 0° and 45°. Additionally, the interface is positioned at an angle of about 0° and 30° with respect to an axis or plane of the viewer, that is substantially horizontal. This provides for various viewing zones to compensate for various heights of users.

The human mechanical interface 20 includes a screen or interface 22 and a bezel 24 for receiving the screen 22. The bezel 24 includes hinge pins 26 that couple the bezel 24 with at least one rotary damper 28. The bezel 24 generally has an overall rectangular design to receive the rectangular screen 22. However, any shape or design could be utilized for the disclosure. The bezel 24 includes lateral legs 30 as well as longitudinal legs 32. The longitudinal legs 32 that includes the pivot pins 26 is opened at the top to enable the interface 22 to slide into the bezel 24. Additionally, that leg could be missing and a U-shape bezel 24 could receive the interface 22 within the channel 34 defined by the legs 30, 32.

The rotary dampers 28 are positioned onto the console 12. The rotary dampers 28 provide for the movement or pivoting rotation of the mechanical interface 20. Thus, when a user presses on the interface 20, the interface rotates away from the console 14 to a position providing one of the desired viewing zones. An additional push on the interface 20 retracts the interface 22 and bezel 24 into the console 14. Thus, this provides various viewing zones to compensate for different heights of users.

Preferably, the interface 20, in its flush position with the console 14, can easily be read by an individual that would be sitting in a wheelchair or the like. Thus, the user would not need to move in order to view the interface 20. Additionally, when the interface is oriented upward, it can be viewed by taller individuals. Additionally, the rotary dampers 28 may enable the interface 22 to move inward into the console 14. This enables an angle pointing downward with respect to the front face 18 of the console 14 so that, if the interface 20 would be part of a stacked combination, a shorter user could readily ascertain the information on the interface 20.

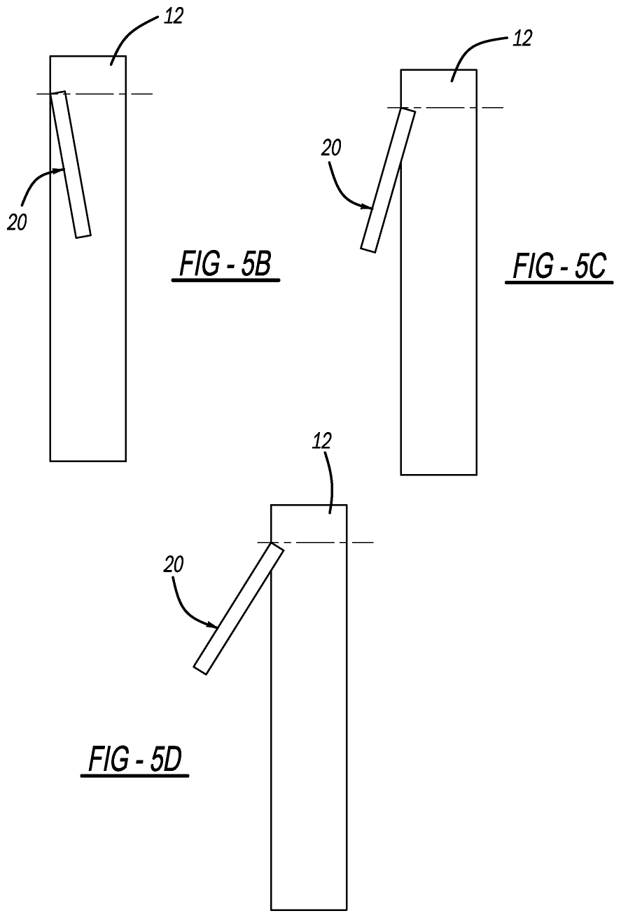

FIG. 5A illustrates the user interface 20 positioned on the front panel of the cabinet 14. Here, the interface 20 is substantially flush with the front face of the cabinet 12. The interface 20 can be moved to a plurality of positions with respect to the cabinet 12 as illustrated in FIGS. 5B-5D. The angle with respect to the cabinet face 14 may vary between −10° to 90° as the user interface 20 swings between positions. In FIG. 5B, the user interface is illustrated in a negative degree position that enables accessibility for a shorter person. In FIG. 5C, the user interface 20 is illustrated in a positive degree position that enables access for a medium to taller person. In FIG. 5D, the user interface 20 is at a larger positive degree position that provides accessibility for a taller person. Thus, the user interface 20 can swing out of the cabinet 12 so that the user interface 20 is substantially perpendicular to the cabinet face 12.

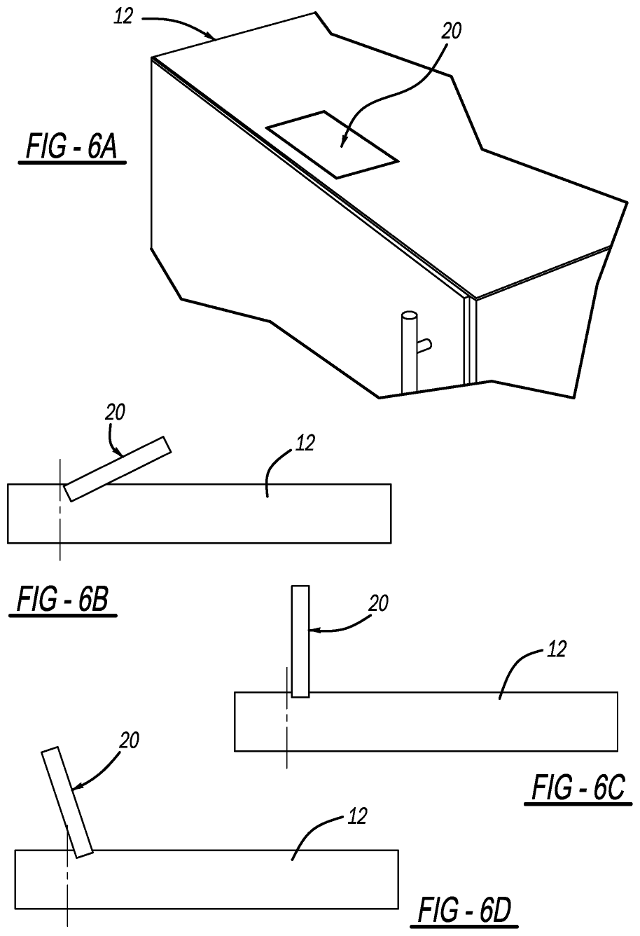

Moving to FIG. 6, the user interface 20 is illustrated on the top plane face of a cabinet 12. Here, the user interface 20 is substantially flush with the top plane of the cabinet 12 and can be moved to a number of positions. The angle with respect to the cabinet 12 top plane may vary between 0° to 100°. This is illustrated in FIGS. 6B-6D. In FIG. 6B, the user interface 20 is illustrated at a small positive angle with respect to the top plane of the cabinet 12. Here, this allows accessibility for a taller person. In FIG. 6C, the user interface 20 is approximately perpendicular with the top plane of the cabinet 14. Here, this allows accessibility for a medium to taller person. FIG. 6D illustrates a user interface 20 angled at approximately 100° faced downward toward horizontal to provide accessibility for a shorter person.

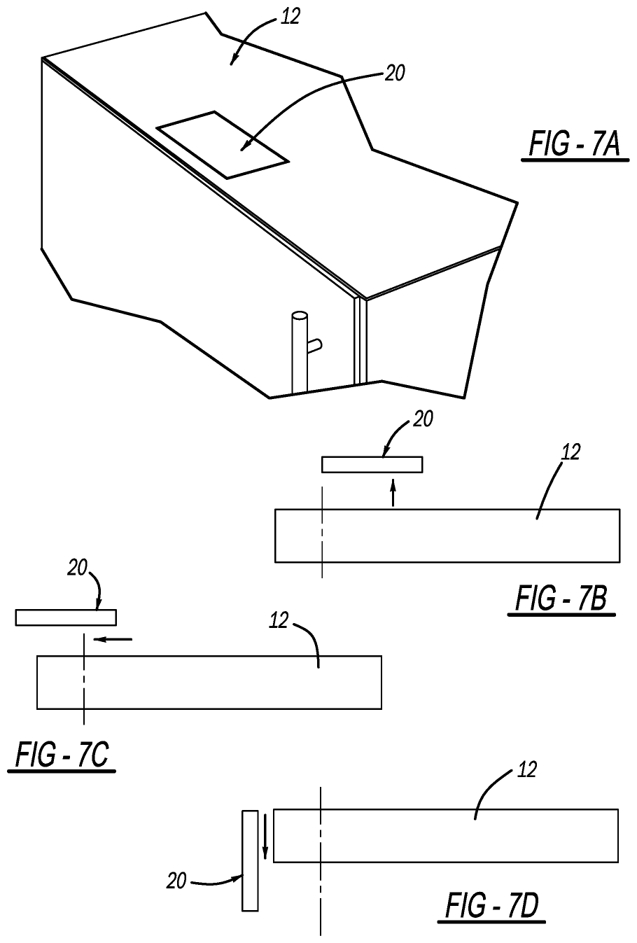

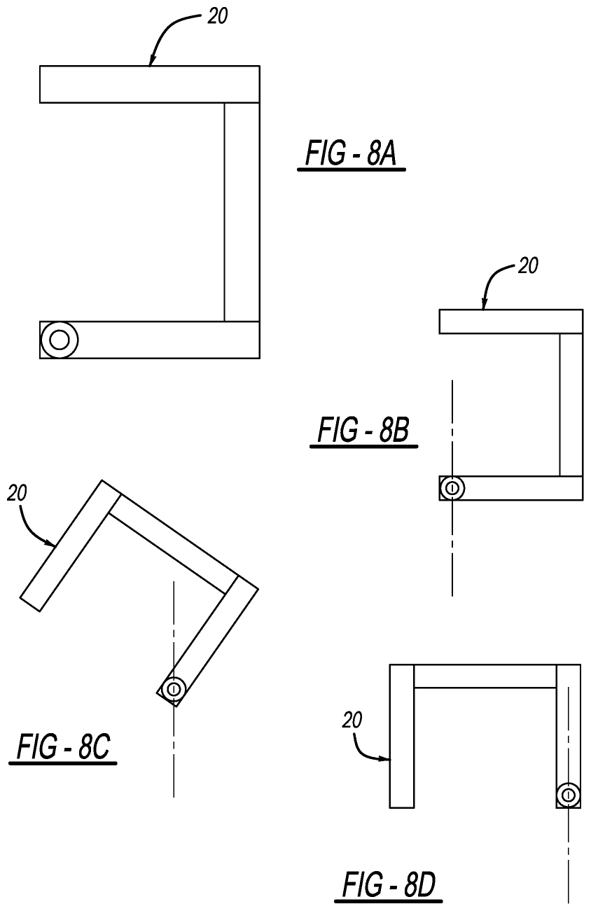

FIG. 7 and FIG. 8 illustrate an additional embodiment. The user interface 20 is positioned on the top plane of the cabinet 12 like that in FIG. 6. However, the user interface 20 pops out of the cabinet 12, via a linkage, to provide a raised user interface 20 as illustrated in FIG. 7B. Here, in the user interface 20 is rotated via the linkage to a position where it is in front of and substantially perpendicular to the front face of the cabinet 12. Thus, this provides an angle with respect to the cabinet top face from between 0° to 270° with respect to the top face of the cabinet 12. As can be seen in FIGS. 8A-8D, the linkage has an overall L-shape and slides along a channel that enables the linkage to be rotated which, in turn, rotates the user interface 20 in the positions illustrated in FIGS. 7B-7D. Thus, depending upon the angle range, the user interface 20 is capable for accommodating taller and shorter people to enable accessibility.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A household appliance comprising:
a cabinet including working operable elements of the appliance;
a control console for the appliance associated with the cabinet;
a human mechanical interface for supplying information to an user associated with the control console, the interface moving with respect to the control console providing a desired viewing zone for a user, the interface further comprising:
a bezel for holding the interface, the bezel being rotatable with respect to the console;
a rotary damper coupled with bezel rotating the bezel, activation of the rotary damper enables the bezel to rotate to one or more viewing zones.

2. The household appliance of claim 1, wherein the bezel includes a pivot hinge defining an axis.

3. The household appliance of claim 2, wherein the hinge is coupled with the rotary damper for enabling rotation.

4. The household appliance of claim 1, wherein the bezel is pushed to rotate with respect to the console to a position providing one of the desired viewing zones.

5. The household appliance of claim 4, wherein an additional push on the bezel retracts the bezel to its original position on the console.

6. The household appliance of claim 1, wherein a ribbon cable is coupled between the interface and controls enabling positioning of the interface.

7. The household appliance of claim 1, wherein the interface is angled with respect to a face of the console at an angle of from about 0° to 45°.

8. The household appliance of claim 1, wherein the interface is positioned at an angle of about 0° to 30° with respect to an axis of the viewer, which is substantially horizontal.

9. The household appliance of claim 1, wherein the viewing zones compensate for various user heights.

10. A human mechanical interface for a household appliance comprising:
a human mechanical interface for supplying information to an user associated with the control console, the interface moving with respect to the control console providing a desired viewing zone for a user, the interface further comprising:
a bezel for holding the interface, the bezel being rotatable with respect to the console;
a rotary damper coupled with the bezel rotating the bezel, activation of the rotary damper enables the bezel to rotate to one or more viewing zones.

11. The human mechanical interface for a household appliance of claim 10, wherein the bezel includes a pivot hinge defining an axis and the hinge is coupled with the rotary damper for enabling rotation.

12. The human mechanical interface for a household appliance of claim 10, wherein the bezel is pushed to rotate with respect to the console to a position providing one of the desired viewing zones and an additional push on the bezel retracts the bezel to its original position on the bezel.

13. The human mechanical interface for a household appliance of claim 10, wherein a ribbon cable is coupled between the interface and controls enabling positioning of the interface.

14. The human mechanical interface for a household appliance of claim 10, wherein the interface is angled with respect to a face of the console at an angle of from about 0° to 45°.

15. The human mechanical interface for a household appliance of claim 10, wherein the interface is positioned at an angle of about 0° to 30° with respect to an axis of the viewer, which is substantially horizontal.

16. A console for a household appliance comprising:
a housing defining a console, the housing including a front face;
a human mechanical interface for supplying information to an user associated with the control console, the interface moving with respect to the control console providing a desired viewing zone for the user, the interface further comprising:
a bezel for holding the interface, the bezel being rotatable with respect to the console;
a rotary damper coupled with bezel rotating the bezel, activation of the rotary damper enables the bezel to rotate to one or more viewing zones.

17. The console for a household appliance of claim 16, wherein the bezel includes a pivot hinge defining an axis and the hinge is coupled with the rotary damper enabling rotation.

18. The console for a household appliance of claim 16, wherein the bezel is pushed to rotate with respect to the console to a position providing one of the desired viewing zones and an additional push on the bezel retracts the bezel to its original position on the console.

19. The console for a household appliance of claim 16, wherein a ribbon cable is coupled between the interface and controls enabling positioning of the interface.

20. The console for a household appliance of claim 1, wherein the interface is angled with respect to the front face of the console at an angle of from about 0° to 45°, and is positioned at an angle of about 0° to 30° with respect to an axis of the viewer, which is substantially horizontal, and the viewing zones compensate for various user heights.
